(19) United States
(12) Patent Application Publication
(10) Pub. No.: US 2008/0023722 A1
(43) Pub. Date: Jan. 31, 2008

(54) Light-emitting heat-dissipating device and packaging method thereof

(75) Inventors: Yi-Sheng Lee, Taoyuan Hsien (TW); Chih-Hao Yu, Taoyuan Hsien (TW); Chin-Ming Cheng, Taoyuan Hsien (TW); Yu-Ping Hsieh, Taoyuan Hsien (TW); Yu-Ching Chang, Taoyuan Hsien (TW); Yi-Hong Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/878,273

(22) Filed: Jul. 23, 2007

(30) Foreign Application Priority Data
Jul. 28, 2006 (TW) 095127657

(51) Int. Cl. H01L 33/00; H01L 21/00

(52) U.S. Cl. 257/99; 438/122; 257/E33.075; 257/E21.002

(57) ABSTRACT

A light-emitting heat-dissipating device includes at least one light-emitting chip and a circuit board. The circuit board has at least one recess and at least one thermally conducting element disposed in the recess. The light-emitting chip is disposed on the thermally conducting element and connected to the circuit board via contact pads electrically connected to a circuit layout of the circuit board. In addition, the light-emitting chip is package by a filler on the circuit board. A packaging method of the light-emitting heat-dissipating device is also disclosed.

### CROSS REFERENCE TO RELATED APPLICATIONS

This Non-provisional application claims priority under 35 U.S.C. §119(a) on Patent Application No(s). 095127657 filed in Taiwan, Republic of China on Jul. 28, 2006, the entire contents of which are hereby incorporated by reference.

### BACKGROUND OF THE INVENTION

1. Field of Invention

The invention relates to a light-emitting heat-dissipating device and a packaging method thereof, and, in particular, to a light-emitting heat-dissipating device for dissipating heat using a heat pipe, and a packaging method thereof.

2. Related Art

Due to the progress of the technology, various electronic products need to have more and more functions. In addition to the continuous upgrade of the speed of the desktop computer, portable mobile electronic devices, such as personalized products including a notebook computer, a mobile phone, a mini CD and a hand-held computer, have become the important trend of the development. However, as the product performance is getting stronger and stronger, the integration of the used electronic element is getting higher and higher, and the generated heat is increased. So, the heat dissipating efficiency influences the reliability and the lifetime of the electronic element.

Illustrations will be made by taking a light emitting diode (LED) package module as an example. Referring to FIG. 1, the conventional LED package module 1 includes a package 11, a LED chip 12 and a lead frame 13. The LED chip 12 is electrically connected to the lead frame 13 by wire bonding and packaged method in the package 11 with an end portion of the lead frame 13 exposed to the package 11. When the LED package module 1 is being used, the heat produced by the LED chip 12 is dissipated through the lead frame 13. Thus, the power of the LED package module is limited to about 0.1 watt. However, when the LED package module 1 is used for a long time, the lead frame 13 cannot effectively dissipate the heat, and the accumulated heat influences the efficiency of the LED chip 12.

As shown in FIG. 2, another conventional LED package module 2 is similar to a combination of the structure of the LED package module 1 of FIG. 1 and a heat slug 21 disposed on a bottom surface of the LED chip 12. One surface of the heat slug 21 is exposed to the bottom surface of the package 11 so that the heat of the LED chip 12 is dissipated through the heat slug 21 and the lead frame 13 simultaneously. The heat slug 21 is made of a heat-conducting metal, such as copper or aluminum. This LED package module 2 is frequently used in the occasion in which the power is about 1 watt.

The heat slug 21 only can dissipate the heat downwards. So, when the LED package module 2 is disposed on a circuit board (not shown), the heat of the LED package module 2 cannot be effectively dissipated but is transferred to the circuit board because the heat slug 21 contacts the circuit board. If the module is used for a long time, the heat dissipated from the LED chip 12 not only deteriorates the heat dissipation efficiency of the LED package module 2 but also makes the LED package module 2 and the circuit board be simultaneously damaged because the heat is conducted to the circuit board.

Therefore, it is an important subject to provide a light-emitting heat-dissipating device capable of quickly conducting the heat and effectively dissipating the heat, and a packaging method thereof.

### SUMMARY OF THE INVENTION

In view of the foregoing, the invention is to provide a light-emitting heat-dissipating device, which is capable of dissipating heat rapidly and has a uniform temperature distribution, and a packaging method thereof.

To achieve the above, the invention discloses a light-emitting heat-dissipating device including at least one light-emitting chip and a circuit board. The circuit board has at least one recess and at least one thermally conducting element disposed in the recess. The light-emitting chip is disposed on the thermally conducting element and packaged on the circuit board. The light-emitting chip is packaged by a filler for protection. The thermally conducting element is preferably a heat pipe. In addition, at least one part of a sidewall of the recess may be further formed with a reflective layer for increasing the light outputting efficiency of a light source.

To achieve the above, the invention also discloses a packaging method of a light-emitting heat-dissipating device. The packaging method includes the steps of: providing a circuit board having at least one recess and a surface formed with a plurality of contact pads connected to a circuit layout in the circuit board; disposing at least one thermally conducting element in the recess; disposing at least one light-emitting chip on the thermally conducting element and electrically connecting the light-emitting chip to the contact pads on the circuit board by way of wire bonding so that the light-emitting chip is electrically connected to the circuit layout of the circuit board; and packaging the light-emitting chip. The thermally conducting element is preferably a heat pipe. Of course, it is also possible to form a reflective layer on at least one part of a sidewall of the recess before the step of packaging the light-emitting chip so that the light outputting efficiency of a light source is increased.

In addition, the invention further discloses a light-emitting heat-dissipating device including at least one light-emitting chip, a circuit board and a carrier. The circuit board has at least one slot. The carrier has a surface formed with at least one recess and at least one thermally conducting element disposed in the recess. The circuit board is disposed on the carrier, and the slot is correspondingly disposed on the recess so that the thermally conducting element is disposed in the slot. The light-emitting chip is disposed on the thermally conducting element and packaged by a filler on the circuit board.

In addition, the invention further discloses a packaging method of a light-emitting heat-dissipating device. The method includes the steps of: providing a carrier having at least one recess formed on one surface of the carrier; disposing at least one thermally conducting element in the recess; disposing a circuit board having at least one slot on the carrier, wherein the slot is correspondingly disposed on the recess so that the thermally conducting element is disposed in the slot; disposing at least one light-emitting chip on the thermally conducting element and electrically connecting the light-emitting chip with the circuit board; and packaging the light-emitting chip by a filler.

As mentioned above, compared with the prior art, the light-emitting chip contacts the thermally conducting element in this invention. So, when the invention is used for a long time, the heat produced by one single light-emitting chip or plural light-emitting chips can be simultaneously, rapidly and uniformly transferred and dissipated in the same direction from the hot junction to the cold junction of the thermally conducting element through the thermally conducting element. This method can achieve the rapid heat dissipation in a short period of time, makes the overall circuit board have the uniform temperature distribution, and thus enhances the reliability and heat dissipating efficiency of the light-emitting heat-dissipating device. In addition, when the circuit board is disposed on the carrier, the thickness of the circuit board may further be reduced so that the manufacturing cost can be reduced. Moreover, the heat dissipating effect may be enhanced by achieving the heat dissipation and rapidly lowering the temperatures of the circuit board and the light-emitting chip through the carrier.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED package module;

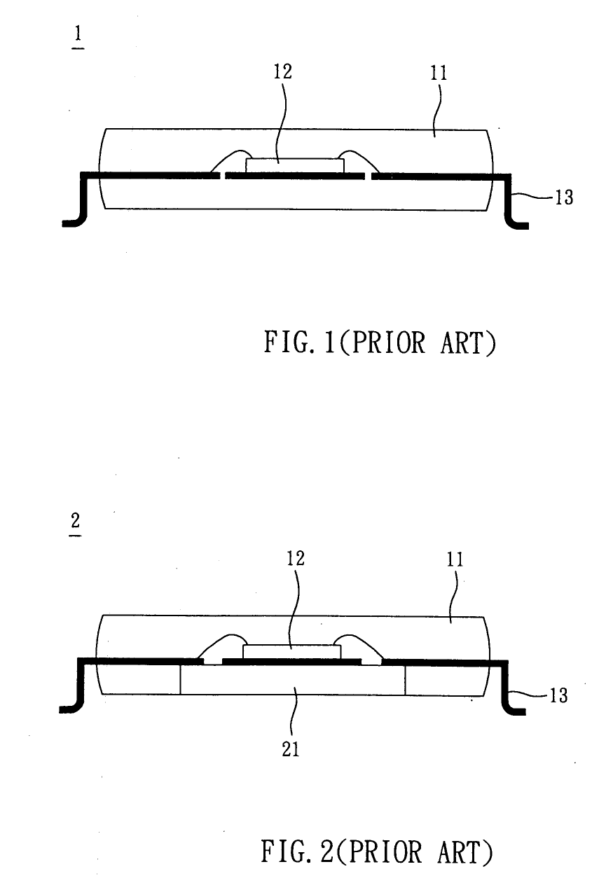

FIG. 2 is a schematic illustration showing another conventional LED package module;

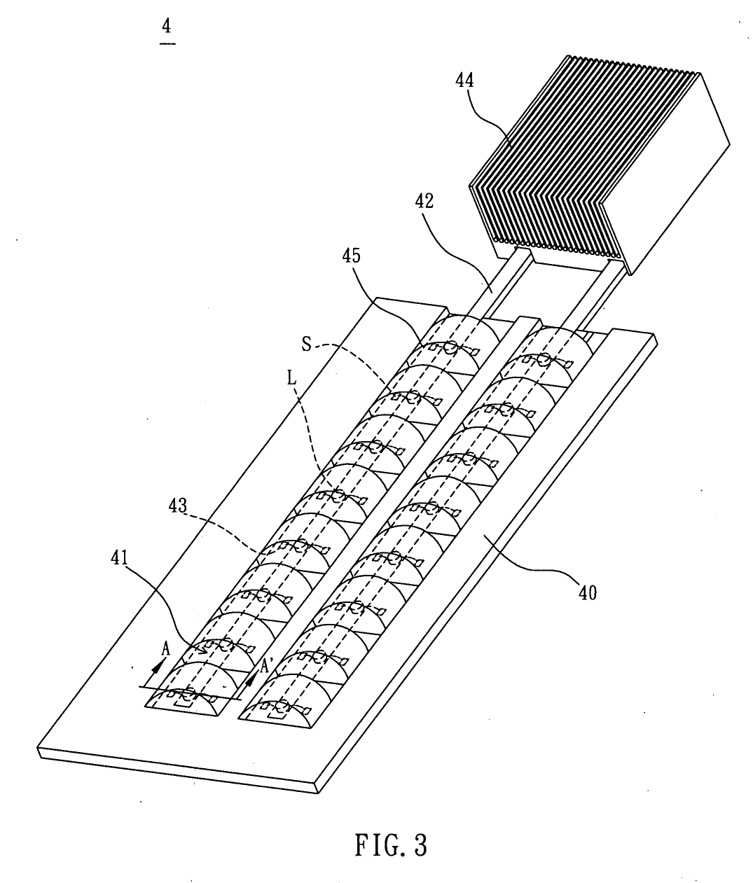

FIG. 3 is a schematic illustration showing a light-emitting heat-dissipating device according to a first embodiment of the invention;

FIG. 4 is a cross-sectional view taken along the A-A′ line segment of FIG. 3;

FIG. 5 is a cross-sectional view showing another light-emitting heat-dissipating device according to the first embodiment of the invention;

FIG. 6 is a flow chart showing a packaging method of the light-emitting heat-dissipating device according to the first embodiment of the invention;

FIGS. 7 to 9 are schematic illustrations showing implementing steps of the packaging method of the light-emitting heat-dissipating device in FIG. 6;

FIG. 10 is a schematic illustration showing a light-emitting heat-dissipating device according to a second embodiment of the invention;

FIG. 11 is a cross-sectional view taken along the B-B′ line segment of FIG. 10;

FIG. 12 is a flow chart showing a packaging method of the light-emitting heat-dissipating device in FIG. 10; and

FIGS. 13 to 15 are schematic illustrations showing implementing steps of the packaging method of the light-emitting heat-dissipating device in FIG. 12.

### DETAILED DESCRIPTION OF THE INVENTION

The present invention will be apparent from the following detailed description, which proceeds with reference to the accompanying drawings, wherein the same references relate to the same elements.

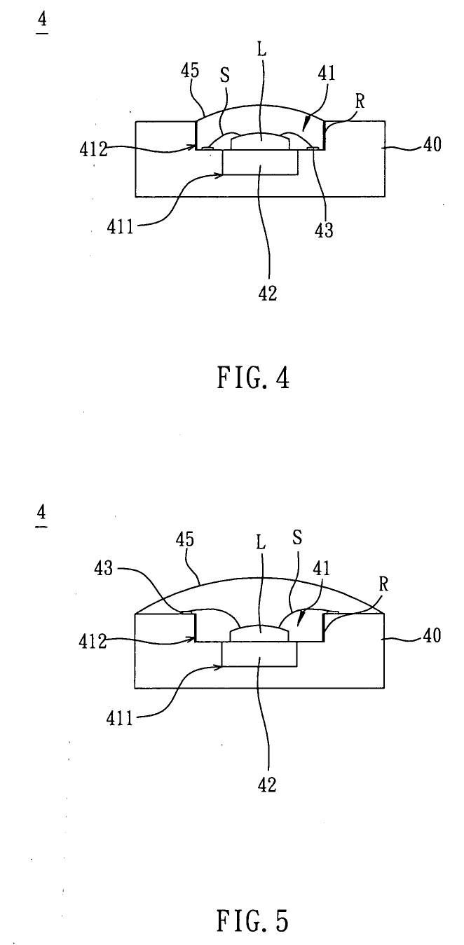

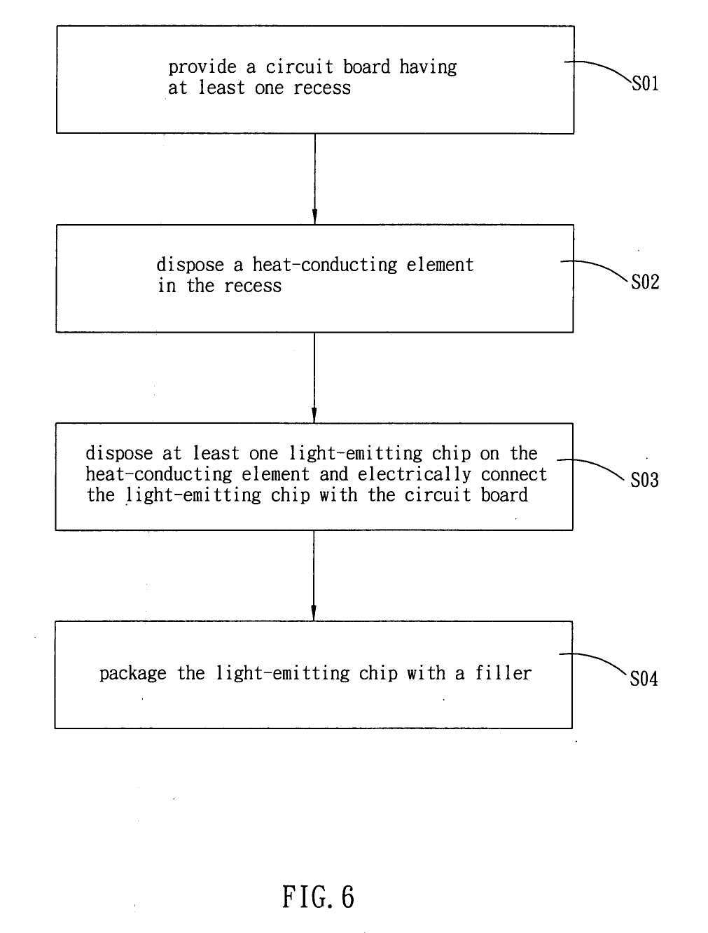

Referring to FIGS. 3 and 4, a light-emitting heat-dissipating device 4 according to a first embodiment of the invention includes a circuit board 40 and at least one light-emitting chip L packaged on the circuit board 40. The circuit board 40 has at least one recess 41 and at least one thermally conducting element 42 disposed in the recess 41. The light-emitting chip L is disposed on the thermally conducting element 42. In this embodiment, the circuit board 40 has a plurality of thermally conducting elements 42, and a plurality of light-emitting chips L is disposed on each thermally conducting element 42.

The circuit board 40 is not particularly restricted and may be a printed circuit board (PCB) or a low-temperature co-fired ceramic (LTCC) circuit board, which is typically used. A plurality of contact pads 43 is exposed from a surface of the circuit board 40 and serves as connections between the light-emitting chip L and a circuit layout of the circuit board 40. The light-emitting chip L is a LED chip, such as a high power light-emitting diode (HP LED), a light-emitting diode array (LED Array), an organic light emitter diode (OLED) or an organic light emitter. diode array (OLED Array). The thermally conducting element 42 is preferably a heat pipe, such as a pulsating heat pipe or a loop heat pipe, having a thermal coefficient greater than about 6000 W/m·K. The light-emitting chip L may be disposed on the thermally conducting element 42 by soldering method, and connected to the contact pads 43 of the circuit board 40 by wire bonding method.

The heat pipe utilizes the cooling technology according to the property of absorbing or dissipating heat during the phase changing procedure. More particularly, the heat pipe is a vacuum body filled with a liquid that may easily evaporate (the evaporating temperature approaches the environment temperature), and is then encapsulated. One end of the heat pipe is an evaporating section, and the other end of the heat pipe is a condensing section. When one end of the heat pipe is heated, the liquid evaporates and vaporizes, and the vapor flows to the other end under the minor pressure difference and releases the heat to condense into the liquid. The liquid flows back to the evaporating section according to the capillary action. Thus, a circulating loop is formed so that the heat may be continuously dissipated. So, the heat pipe is suitable for the heat dissipation of the light-emitting chip L with any power, and is particularly suitable for the heat dissipation of the light-emitting chip with the high power.

In this embodiment, the recess 41 comprises a first recess 411 and a second recess 412 formed on the surface of the circuit board 40. The first recess 411 associates with the second recess 412, and the first recess 411 is deeper than the second recess 412. The first recess 411 is sized to just receive the thermally conducting element 42 and has a longitudinal structure in this embodiment. The thermally conducting element 42 is embedded in the first recess 411 by embedding, adhering or soldering method. The contact pads 43 of the circuit board 40 are formed on a bottom surface of the second recess 412, and the light-emitting chip L is formed with connecting wires S to be electrically connected to the contact pads 43 of the circuit board 40 by wire bonding method. According to the circuit layout in the circuit board 40, the light-emitting chips L may be connected in parallel, in series or in parallel and in series by any suitable method. Because the circuit layout can be easily implemented in the prior art and does not pertain to the most important feature of the invention, detailed descriptions thereof will be omitted.

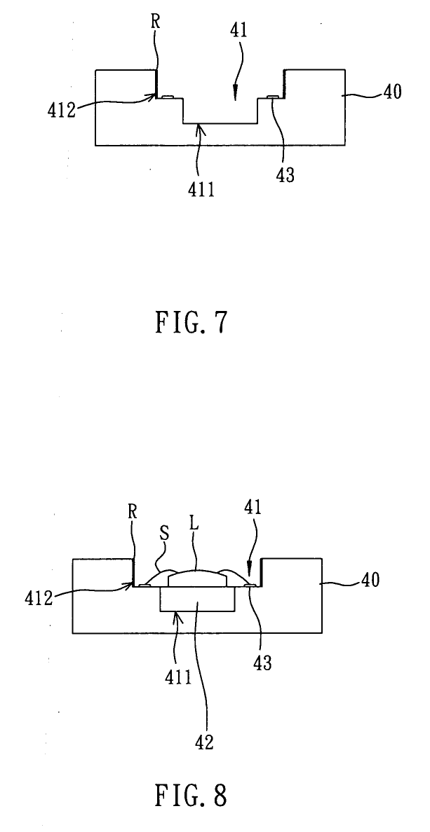

In order to enhance the light reflecting effect, a reflective layer R may be formed on a sidewall of the second recess 412. Of course, the contact pads 43 electrically connected to the light-emitting chip L may also be formed on a top surface of the circuit board 40, as shown in FIG. 5. At last, the recess 41, the light-emitting chip L and the connecting wires S connected to the contact pads 43 are packaged by a filler 45 and are thus not exposed to the outside. The filler 45 is not particularly restricted and may be plastic or resin, such as epoxy resin or silica gel.

Referring again to FIG. 3, the thermally conducting element 42 in this embodiment has one end, which extends out of the circuit board 40 and is connected to a heat dissipating element 44. The heat dissipating element 44 is not particularly restricted and may be a heat sink having a plurality of heat dissipating fins. The heat dissipating element 44 dissipates the heat introduced by the thermally conducting element 42. The heat dissipating effect of the heat dissipating element 44 may further be enhanced by a fan (not shown) for producing an air stream to blow the heat dissipating element 44. When the light-emitting heat-dissipating device 4 is operating, the heat produced by the light-emitting chip L is guided out through the thermally conducting element 42 and transferred to the heat dissipating element 44 so that the heat can be dissipated. Because the light-emitting heat-dissipating device 4 guides the heat produced by the light-emitting chip L through the thermally conducting element 42 in the same direction, i.e., from one end (hot junction) of the thermally conducting element 42 contacting the light-emitting chip L to the other end (cold junction) of the thermally conducting element 42, and then the heat is transferred to the heat dissipating element 44 for dissipating the heat. Dissipating the heat in this manner enables the heat of the light-emitting chip(s) L to be simultaneously, uniformly and rapidly dissipated, no matter one single light-emitting chip L or a plurality of light-emitting chips L are used. In addition, the overall circuit board 40 has the uniform temperature distribution, and the reliability and the heat dissipating efficiency of the light-emitting heat-dissipating device 4 can be enhanced.

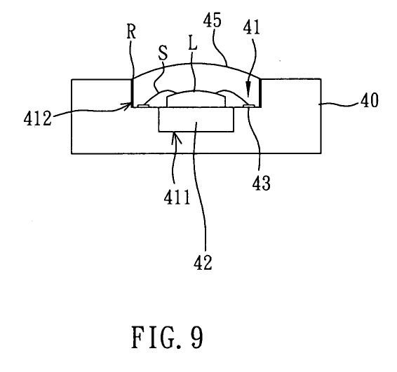

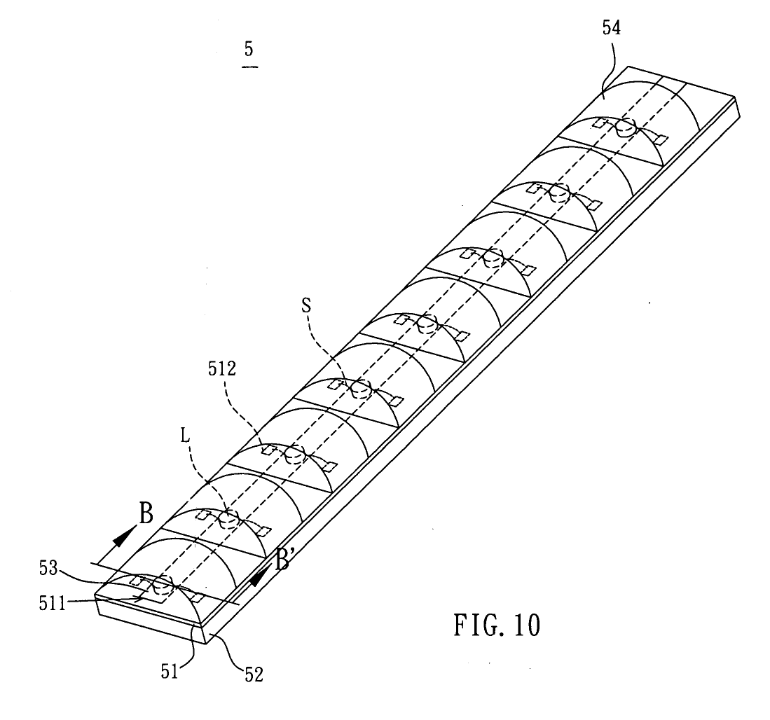

Referring to FIG. 6, a packaging method of the light-emitting heat-dissipating device 4 according to the first embodiment includes steps S01 and S04. As shown in FIG. 7, step S01 is performed to provide a circuit board 40 having at least one recess 41. The surface of the circuit board 40 has a plurality of contact pads 43 connected to a circuit layout in the circuit board 40. The recess 41 may further be divided into a first recess 411 and a second recess 412. The second recess 412 is formed on the surface of the circuit board 40, and the first recess 411 communicates with the second recess 412 and is deeper than the second recess 412. A reflective layer R may further be formed on a sidewall of the second recess 412.

As shown in FIG. 8, step S02 is performed to dispose a thermally conducting element 42 in the recess 41, wherein the thermally conducting element 42 is disposed in the first recess 411 in this embodiment. Step S03 is performed to dispose at least one light-emitting chip L on the thermally conducting element 42 and electrically connect the light-emitting chip L with the contact pads 43 of the circuit board 40 by way of wire bonding. In this embodiment, the light-emitting chip L is, disposed on the thermally conducting element 42 by way of soldering.

As shown in FIG. 9, step S04 is performed to package the light-emitting chip L with a filler 45. The packaged light-emitting chip L disables the external moisture or dust from entering the recess 41 and thus damaging the light-emitting chip L and the connecting wires S so that the reliability of each of the light-emitting heat-dissipating device 4 and the circuit board 40 may be enhanced. In addition, before or after the circuit board 40 is packaged, a heat dissipating element 44 may be connected to an end portion of the thermally conducting element 42 (see FIG. 3) so that the heat dissipating efficiency of the circuit board 40 may be increased.

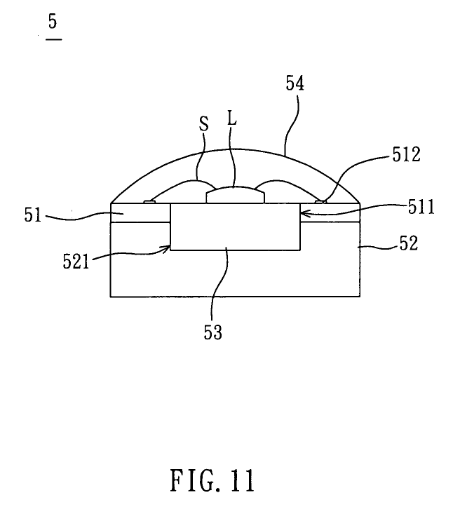

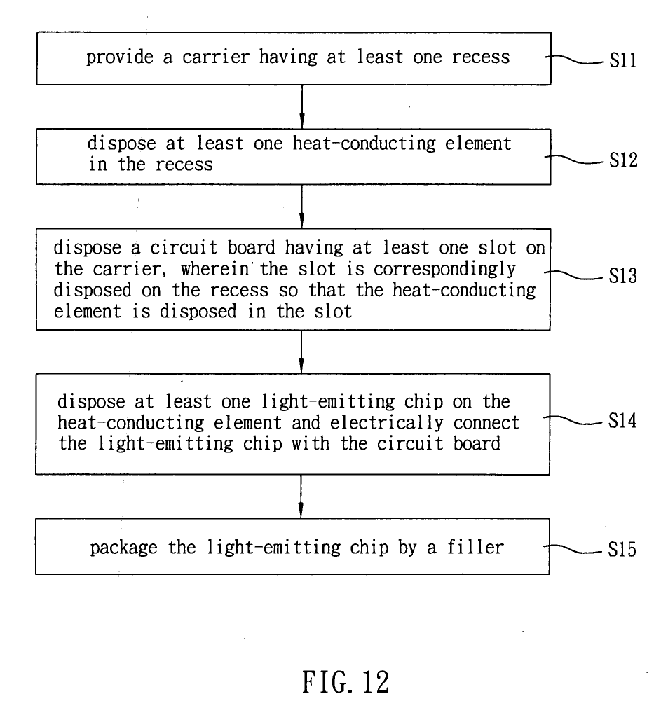

Referring to FIGS. 10 and 11, a light-emitting heat-dissipating device 5 according to a second embodiment of the invention includes at least one light-emitting chip L, a circuit board 51 and a carrier 52.

The circuit board 51 has a slot 511 and one surface of the carrier 52 has at least one recess 521 and at least one thermally conducting element 53 disposed in the recess 521. In this embodiment, the carrier 52 has a recess 521 and a thermally conducting element 53. The circuit board 51 is disposed on the carrier 52, and the slot 511 is correspondingly disposed on the recess 521 so that the thermally conducting element 53 is also disposed in the slot 511, and the light-emitting chip L is disposed on the thermally conducting element 53 and packaged on the circuit board 51.

The structures, features and effects of the light-emitting chip L and the thermally conducting element 53 of this embodiment are the same as those of the light-emitting chip L and the thermally conducting element 42 of the above-mentioned embodiment (see FIGS. 3 and 4), so detailed descriptions thereof will be omitted.

The circuit board 51 may be a printed circuit board or a low-temperature co-fired ceramic circuit board, which is typically used, and the circuit board 51 has a circuit layout (not shown). The circuit layout is not particularly restricted and may be connected in series or in parallel. The circuit board 51 has a plurality of contact pads 512 connected to the circuit layout. The light-emitting chips L are electrically connected to the contact pads 512 via the connecting wires S by way of wire bonding. Finally, the light-emitting chips L, the contact pads 512 and the connecting wires S are packaged by a filler 54 and are thus not exposed to the outside.

In addition, the material of the carrier 52 of this embodiment is not particularly restricted, and may be a heat conducting material, such as a metal material or a polymer. In this embodiment, the composition, feature and effect of the filler 54, the connecting wire S and the contact pad 512 are the same as those of the filler 45, the connecting wire S and the contact pad 43 of the above-mentioned embodiment (see FIGS. 3 and 4), so detailed descriptions thereof will be omitted.

Because the thermally conducting element 53 is disposed in the recess 521 of the carrier 52 in the light-emitting heat-dissipating device 5, the heat produced by the light-emitting chip L after being used for a period of time is conducted to the carrier 52 by the thermally conducting element 53. Since the carrier 52 is disposed under the circuit board 51, the heat may be rapidly dissipated in a short period of time, and the temperatures of the light-emitting chip L and the circuit board 51 may be lowered so that the heat dissipating effect is enhanced.

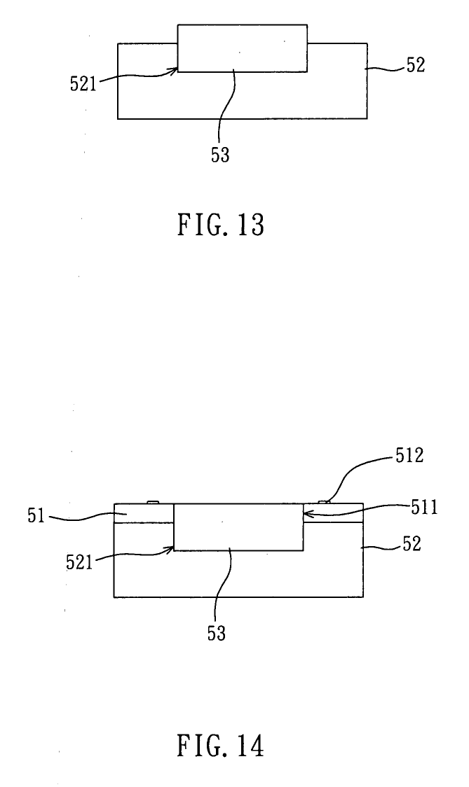

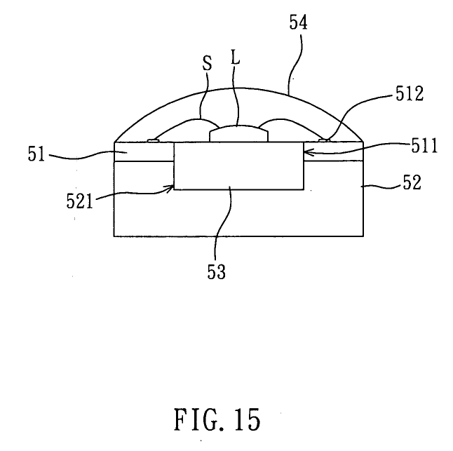

Referring to FIG. 12, the packaging method of the light-emitting heat-dissipating device 5 of the second embodiment includes steps S11 to S15. As shown in FIGS. 12 and 13, step S11 is performed to provide a carrier 52 having at least one recess 521, wherein the recess 521 is formed on a surface of the carrier 52. Step S12 is performed to dispose at least one thermally conducting element 53 in the recess 521 with the thermally conducting element 53 being exposed from the recess 521.

As shown in FIG. 14, step S13 is performed to dispose a circuit board 51 having at least one slot 511 on the carrier 52, wherein the slot 511 is correspondingly disposed on the recess 521 so that the thermally conducting element 53 is disposed in the slot 511. The circuit board 51 is the printed circuit board or the low-temperature co-fired ceramic circuit board, which is typically used, and has a plurality of contact pads 512 connected to the circuit layout in the circuit board.

As shown in FIG. 15, step S14 is performed to dispose at least one light-emitting chip L on the thermally conducting element 53 and electrically connect the light-emitting chip L with the circuit board 51. The light-emitting chip L is connected to the contact pads 512 via the connecting wires S by wire bonding method. Step S15 is performed to package the light-emitting chip L by a filler 54 so as to prevent the moisture or the dust from entering the light-emitting chip L, and thus to enhance the reliability of the light-emitting heat-dissipating device 5.

In summary, compared with the prior art, the light-emitting chip contacts the thermally conducting element in this invention. So, the heat produced by the light-emitting chip can be simultaneously, rapidly and uniformly transferred and dissipated in the same direction from the hot junction to the cold junction of the thermally conducting element through the thermally conducting element. This method can achieve the rapid heat dissipation in a short period of time, makes the overall circuit board have the uniform temperature distribution, and thus enhances the reliability and heat dissipating efficiency of the light-emitting heat-dissipating device. In addition, when the circuit board is disposed on the carrier, the thickness of the circuit board may further be reduced so that the manufacturing cost can be reduced.

Although, the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting heat-dissipating device, comprising:
at least a light-emitting chip;
a substrate having at least a recess; and
at least a thermally conducting element disposed in the recess, wherein the light-emitting chip is disposed on the thermally conducting element and packaged on the substrate by a filler.

2. The device according to claim 1, wherein the thermally conducting element is a heat pipe, the heat pipe is a pulsating heat pipe or a loop heat pipe.

3. The device according to claim 2, wherein the heat pipe has a thermal coefficient greater than 6000 W/m·K.

4. The device according to claim 1, wherein the thermally conducting element is disposed in the recess by embedding, adhering or soldering.

5. The device according to claim 1, wherein the thermally conducting element has one end extending out of the substrate and connected to a heat dissipating element having a plurality of heat dissipating fins.

6. The device according to claim 1, wherein the light-emitting chip is a light-emitting diode, a high-power light-emitting diode, a light-emitting diode array, an organic light emitter diode or an organic light emitter diode array, and the light-emitting chip is disposed on the thermally conducting element by soldering.

7. The device according to claim 1, wherein the substrate is a printed circuit board or a low-temperature co-fired ceramic (LTCC) circuit board.

8. The device according to claim 1, further comprising a supporter disposed below the substrate and having a slot formed thereof.

9. The device according to claim 8, wherein the slot is located corresponding to the recess, and the thermally conducting element is disposed in the recess and the slot.

10. The device according to claim 8, wherein the supporter is made of metal, a thermal-conducting material or a polymer.

11. The device according to claim 1, wherein the recess comprises a first recess and a second recess, the second recess is formed on the substrate, and the first recess communicate with the second recess and is formed in the substrate.

12. The device according to claim 11, wherein the thermally conducting element is embedded in the first recess, and a reflective layer is formed on a sidewall of the second recess.

13. The device according to claim 11, wherein the substrate has a circuit layout and a plurality of contact pads connected to the circuit layout, the contact pads are formed on the surface of the substrate or a bottom surface of the second recess, and the light-emitting chip is connected to the contact pads by wire bonding.

14. The device according to claim 1, wherein the filler is plastic, resin, silica gel, or epoxy resin.

15. A packaging method of a light-emitting heat-dissipating device, the method comprising the steps of:
providing a substrate having at least a recess;
disposing at least a thermally conducting element in the recess;
disposing at least a light-emitting chip on the thermally conducting element to be electrically connected to the substrate; and
packaging the light-emitting chip by a filler.

16. The method according to claim 15, wherein the thermally conducting element is a heat pipe, a pulsating heat pipe or a loop heat pipe.

17. The method according to claim 16, wherein the heat pipe has a thermal coefficient greater than 6000 W/m·K.

18. The method according to claim 15, wherein the thermally conducting element is disposed in the recess by embedding, adhering or soldering.

19. The method according to claim 15, wherein the thermally conducting element has one end extending out of the circuit board and connected to a heat dissipating element having a plurality of heat dissipating fins.

20. The method according to claim 15, further comprising a step of providing a supporter disposed below the substrate, the supporter having a slot formed thereof.

21. The method according to claim 15, wherein the thermally conducting element is embedded in the first recess, and a reflective layer is formed on a sidewall of the second recess.

22. The method according to claim 15, wherein the substrate has a circuit layout and a plurality of contact pads connected to the circuit layout, the contact pads are formed on the surface of the substrate or a bottom surface of the recess, and the light-emitting chip is connected to the contact pads by wire bonding.
